(19) United States
(12) Patent Application Publication
(10) Pub. No.: US 2006/0274500 A1
(43) Pub. Date: Dec. 7, 2006

(54) Heat radiating structure for CPU

(75) Inventor: Kunimakoto Nagayumi, Shizuoka (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Toshiba Tec Kabushiki Kaisha, Tokyo (JP)

(21) Appl. No.: 11/433,125

(22) Filed: May 12, 2006

(30) Foreign Application Priority Data
May 31, 2005 (JP) 2005-159029

(51) Int. Cl. H05K 7/20

(52) U.S. Cl. 361/688

(57) ABSTRACT

A CPU is mounted on a printed circuit board which is affixed to a case, an opening is formed at a position of the printed circuit board facing a surface of the CPU, and a heat conductor for transmitting heat extends through the opening so as to contact the surface of the CPU and a radiator.

### CROSS-REFERENCE TO RELATED APPLICATION

The present application is based on and claims the benefit of priority of Japanese Patent Application 2005-159029 filed on May 31, 2005, the entire contents of which are incorporated herein by reference.

### BACKGROUND OF THE INVENTION

1. Field of the Invention

The present invention relates to a heat radiating structure for a CPU, and especially relates to a heat radiating structure which prevents a rise in temperature of a CPU without utilizing a cooling fan.

2. Discussion of Related Art

In recent years, an amount of heat radiated from electronic devices tends to increase as the electronic devices have been attaining high density, miniaturization, and high performance. Especially, the amount of heat radiated from a CPU has been remarkably increased. In general, in order to cool off the CPU, a structure shown in FIG. 1 is adopted. That is, a printed circuit board 3 is provided on a sheet-metal case 1 via a spacer 2, and a CPU 4 is mounted on the printed circuit board 3 with a certain space therebetween. To cool off the CPU 4, a heatsink 6 is provided on an upper surface of the CPU 4 via thermal grease 5, or the like, and the heatsink 6 transmits heat generated from the CPU 4, and thereby prevents a rise in temperature of the CPU 4.

There is another example of a conventional structure disclosed in Japanese Laid-Open Publication No. 2004-363525. This publication discloses a structure that is similar to the structure shown in FIG. 1 in that a printed circuit board is attached to a case, and a CPU is mounted on the printed circuit board. In addition, this structure has a heat radiating plate that is adhered to an upper surface of the CPU, and a heatsink that is attached to the heat radiating plate.

Although the conventional structure has a strong capability of heat radiation from the upper surface of the CPU, heat radiation can only be performed from one surface of the CPU. Thus, even if the heatsink radiates heat effectively, heat transfer can be performed one-sidedly. Therefore, the entire structure does not necessarily perform the heat radiation effectively. Further, the heatsink attached to the upper surface of the CPU requires a certain height to assure necessary heat capacity. It is therefore difficult to reduce the height, and downsizing of a device as a whole should be limited.

Accordingly, an object of the present invention is to provide a heat radiating structure for a CPU to prevent a rise in temperature of the CPU effectively, and another object of the present invention is to downsize the device.

### SUMMARY OF THE INVENTION

To achieve the object of the present invention, a heat radiating structure for a CPU is provided which includes: (i) a printed circuit board, (ii) a CPU mounted on the printed circuit board, (iii) an opening formed at a position of the printed circuit board facing a surface of the CPU, (iv) a radiator for radiating heat, and (v) a heat conductor which contacts the radiator and extends through the opening to contact the surface of the CPU that faces the opening, so as to transmit heat from the CPU to the radiator.

### BRIEF DESCRIPTION OF THE DRAWINGS

A more complete appreciation of the present invention and many of the attendant advantages thereof will be readily obtained as the same becomes better understood by reference to the following detailed description when considered in connection with the accompanying drawings, wherein:

FIG. 1 is a side view in vertical section showing an example of a conventional structure;

FIG. 2 is a side view in vertical section showing an embodiment of the present invention;

FIG. 3 is a side view in vertical section showing a variation of the embodiment of the present invention; and

FIG. 4 is a side view in vertical section showing another variation of the embodiment of the present invention.

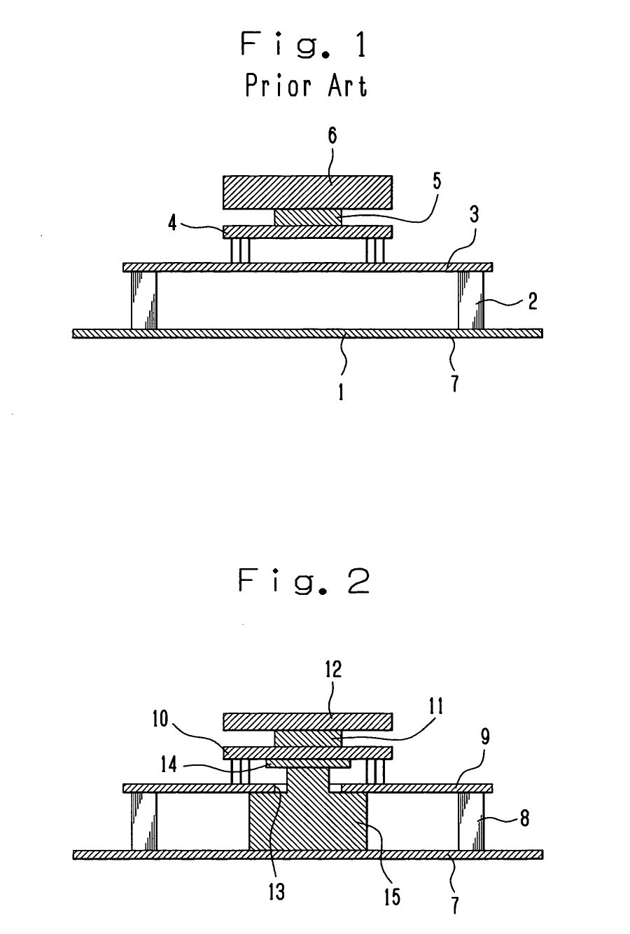

### DETAILED DESCRIPTION OF THE PREFERRED EMBODIMENTS

An embodiment of the present invention will be described with reference to FIGS. 2 to 4. First of all, a printed circuit board 9 is provided on a sheet-metal case 7 functioning as a radiator via a spacer 8, and a CPU 10 is mounted on the printed circuit board 9 with a certain space. A heatsink 12 is attached onto an upper surface of the CPU 10 via thermal grease 11, or the like. The thermal grease 11 is a sort of paste, which functions to enhance heat conductivity by firmly attaching the upper surface of the CPU 10 and a lower surface of the heatsink 12. This will improve heat conductivity due to exclusion of an air layer which may act as a heat insulating layer.

An opening 13 having a predetermined size is formed at a position of the printed circuit board 9 which faces the CPU 10. A heat conductor 15 including the heat radiating sheet 14 is provided through the opening 13 between the lower surface of the CPU 10 and the case 7. The heat radiating sheet 14 has flexibility and adheres to the lower surface of the CPU 10 to enhance heat conductivity. Any member can be adopted as the heat conductor 15 if the member has high heat conductivity to the case 7, which has a large surface area exposed to the air so as to function as the radiator. For example, for the heat conductor 15, a condenser can be adopted that has an outer case made of aluminum, or the like, and which has high heat conductivity.

As for the radiator, not only the case 7 as explained above, but also a chassis to which the printed circuit board 9 is affixed, a heatsink, and so on can be used.

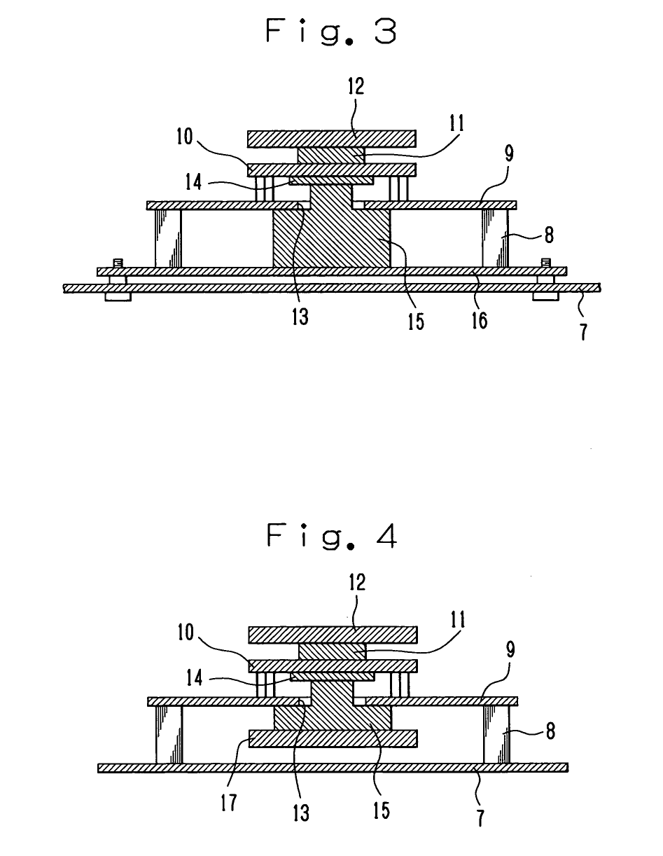

FIGS. 3 and 4 are other variations of the embodiment of the present invention. Although the printed circuit board 9 is affixed to the case 7 directly via the spacer 8 in the embodiment explained above, another structure can be adopted such that the printed circuit board 9 is affixed via the spacer 8 to a metal chassis 16, which functions as the radiator, and then the metal chassis 16 is attached to the case 7 (see FIG. 3). Alternatively, if a heatsink is adopted as the radiator, the heatsink as the radiator (not shown) can be attached to an outside surface of the case 7, on an outer side of the inside surface of the case 7 where the heat conductor 15 provided between the lower surface of the CPU 10 and the case 7 makes contact. Also, as shown in FIG. 4, if a structure that a heatsink 17 is provided inside the case 7 is adopted, the heatsink 17 can be attached to a surface of the heat conductor 15 opposite to the surface that makes contact with the lower surface of the CPU 10.

That is, either a specific member especially designed for heat radiation of the CPU 10 or a member not designed for heat radiation but that happens to be useful for heat radiation can be used as the radiator, and the present invention is not limited to the structures explained above.

According to the structure explained above, heat generated from the CPU 10 can be radiated from both sides (the upper surface and the lower surface) of the CPU 10. That is, from the lower surface of the CPU 10, heat generated from the CPU 10 is transmitted to the case 7 through the heat conductor 15 which includes the heat radiating sheet 14 so that the CPU 10 can be cooled off effectively. Especially, since the heat conductor 15 is provided through the opening 13 which is formed in the printed circuit board 9 having high heat insulating properties, the structure of the present embodiment does not keep heat at the lower surface of the CPU 10 which faces the printed circuit board 9, and has a high cooling capability. The upper surface of the CPU 10 is cooled off by the heatsink 12 in a manner similar to the conventional structure. Further, as a result of heat radiation from the lower surface of the CPU 10, the amount of heat radiation from the upper surface of the CPU 10 can be lower than that of the conventional structure. Therefore, it can be possible to downsize the height of the heatsink 12, thereby making it possible to reduce the height from the case 7 to an upper surface of the heatsink 12 so that downsizing of a device can be realized. That is, the height of the device itself can be reduced. By cooling off the CPU 10 from both sides (the upper surface and the lower surface) of the CPU 10, sufficient heat radiation can be performed so that a fan-free structure is adoptable, which does not require a cooling fan. Thus, downsizing and cost-reducing of the device can be accomplished.

Obviously, numerous modifications and variations of the present invention are possible in light of the above teachings. It is therefore to be understood that within the scope of the appended claims, the invention may be practiced otherwise than as specifically described herein.

What is claimed is:

1. A heat radiating structure for a CPU comprising:
a printed circuit board;
a CPU mounted on the printed circuit board;
an opening formed at a position of the printed circuit board facing a surface of the CPU;
a radiator for radiating heat; and
a heat conductor which contacts the radiator and extends through the opening to contact the surface of the CPU that faces the opening, so as to transmit heat from the CPU to the radiator.

2. The heat radiating structure for a CPU according to claim 1, wherein the radiator comprises a metal case.

3. The heat radiating structure for a CPU according to claim 1, wherein the radiator comprises a metal chassis.

4. The heat radiating structure for a CPU according to claim 1, wherein the radiator comprises a heatsink.
